(19) United States
(12) Patent Application Publication
(10) Pub. No.: US 2009/0170299 A1
(43) Pub. Date: Jul. 2, 2009

(54) FORMING A METAL CONTACT IN A SEMICONDUCTOR DEVICE

(75) Inventor: Whan Ki LEE, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/266,411

(22) Filed: Nov. 6, 2008

(30) Foreign Application Priority Data
Dec. 27, 2007 (KR) 10-2007-0138484

(51) Int. Cl. H01L 21/266

(52) U.S. Cl. 438/533; 257/E21.346

(57) ABSTRACT

Methods for forming a metal contact in a semiconductor device. In one example embodiment, a method for forming a metal contact in a semiconductor device includes various steps. First, an interlayer insulating film is formed over a silicon substrate. Next, an insulating film is formed over the interlayer insulating film. Then, a photoresist pattern is formed on the insulating film. Next, the insulating film, the interlayer insulating film, and the silicon substrate are selectively etched using the photoresist pattern as an etch mask in order to form a contact trench. Then, the photoresist pattern is removed. Next, impurity ions are implanted into a region beneath the contact trench using the selectively-etched insulating film as a mask. Then, the selectively-etched insulating film and the contact trench are isotropically etched. Next, the contact trench is filled with a metal material.

### CROSS-REFERENCE TO A RELATED APPLICATION

This application claims the benefit of Korean Patent Application No. 10-2007-0138484, filed on Dec. 27, 2007 which is hereby incorporated by reference as if fully set forth herein.

### BACKGROUND

1. Field of the Invention

Embodiments of the present invention relate to a semiconductor device, and more particularly, to methods for forming a metal contact in a semiconductor device.

2. Description of the Related Art

As semiconductor devices become increasingly integrated, the channel length of transistors used in semiconductor devices has been shortened. However, the shortening of the channel length causes an abrupt decrease in the threshold voltage of the transistor, known as a short channel effect. When the channel length of a transistor is shortened, it becomes necessary to implant an increased amount of channel ions in order to improve the punchthrough characteristics of the transistor between a source and a drain.

One type of transistor is a recessed gate transistor. In a recessed gate transistor, a recess is formed in a silicon substrate in order to increase the length of a channel, and thus eliminate the short channel effect. In a semiconductor device in which a plurality of recessed gate transistors are formed on a silicon substrate and metal contacts are formed in gate and source regions of each recessed transistor, respectively, trenches are also formed between two adjacent recessed transistors to provide metal contacts.

FIGS. 1A to 1G are sectional views illustrating sequential processes of a prior art method for forming a metal contact in a silicon substrate formed with general recessed gate transistors.

As shown in FIG. 1A, two recessed gate transistors are formed on a silicon substrate (not shown) formed with an epitaxial layer 10 and a P-type body 20. Each of the recessed gate transistors includes a gate oxide film 30, a polysilicon layer 40, a source region 50, and a gate oxide film 60. Next, an interlayer insulating film 70, which is formed from pre-metal dielectric (PMD), is formed over the silicon substrate.

As shown in FIG. 1B, a photoresist pattern 75 is next formed on the interlayer insulating film 70. As shown in FIG. 1C, using the photoresist pattern 75 as an etch mask, the interlayer insulating film 70 is next selectively etched resulting in a partially-etched interlayer insulating film 70′ and partially exposing the P-type body 20. As shown in FIG. 1D, the exposed P-type body 20 is next selectively etched, using the photoresist pattern 75 as an etch mask, to form contact trenches 82, 84, and 86.

As shown in FIG. 1E, the photoresist pattern 75 is next removed. Impurity ions are then implanted into the contact trenches 82, 84, and 86. The photoresist pattern is removed prior to the implantation of the impurity ions in order to avoid limiting the ion implantation tilt in the impurity ion implantation process.

As shown in FIG. 1F, the contact trenches 82, 84, and 86 are next further etched such that they extend further into the impurity ion implantation region, to form deep contact trenches 92, 94, and 96. As shown in FIG. 1G, the deep contact trenches 92, 94, and 96 are next filled in with a metal material. Since the etch that forms the deep contact trenches 92, 94, and 96 is carried out without using a photoresist pattern, the partially-etched interlayer insulating film 70′ is also etched during the etch process.

As a result, the thickness of the partially-etched interlayer insulating film 70′ is reduced, and an increase in an aspect ratio corresponding to the depth of the contact trenches occurs, resulting in voids forming during a subsequent process for filling a metal layer, thereby causing insulation failure and contact failure.

### SUMMARY OF EXAMPLE EMBODIMENTS

In general, example embodiments of the present invention relate to a method for forming a metal contact in a semiconductor device. Some example embodiments are capable of preventing a reduction in the thickness of an interlayer insulating film during formation of a contact trench, resulting in a reduction in the incidence of insulation failure and contact failure.

In one example embodiment, a method for forming a metal contact in a semiconductor device includes various steps. First, an interlayer insulating film is formed over a silicon substrate. Next, an insulating film is formed over the interlayer insulating film. Then, a photoresist pattern is formed on the insulating film. Next, the insulating film, the interlayer insulating film, and the silicon substrate are selectively etched using the photoresist pattern as an etch mask in order to form a contact trench. Then, the photoresist pattern is removed. Next, impurity ions are implanted into a region beneath the contact trench using the selectively-etched insulating film as a mask. Then, the selectively-etched insulating film and the contact trench are isotropically etched. Next, the contact trench is filled with a metal material.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

Aspects of example embodiments of the present invention will become apparent from the following detailed description of example embodiments given in conjunction with the accompanying drawings, in which:

FIGS. 1A to 1G are sectional views illustrating sequential processes of a prior art method for forming a metal contact in a silicon substrate formed with general recessed gate transistors; and

FIGS. 2A to 2H are sectional views illustrating sequential processes of an example method for forming a contact trench in a semiconductor device.

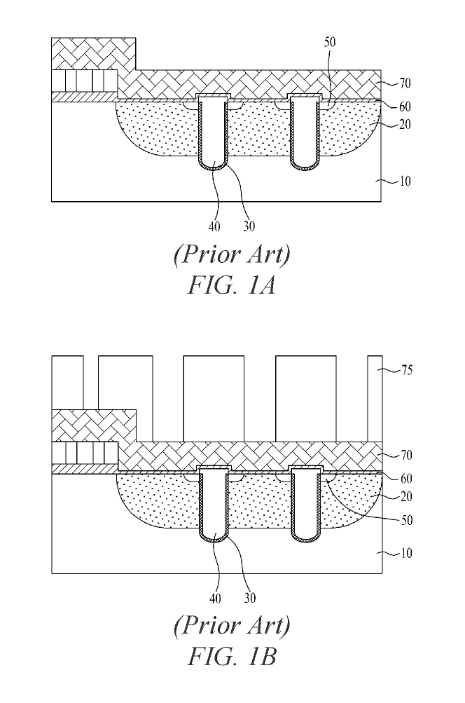

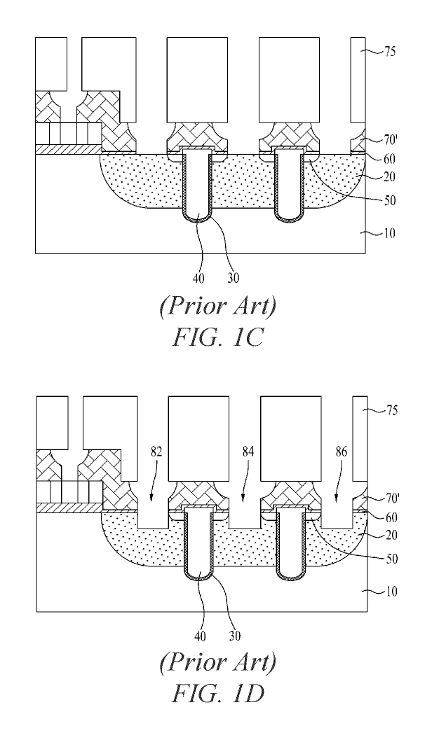

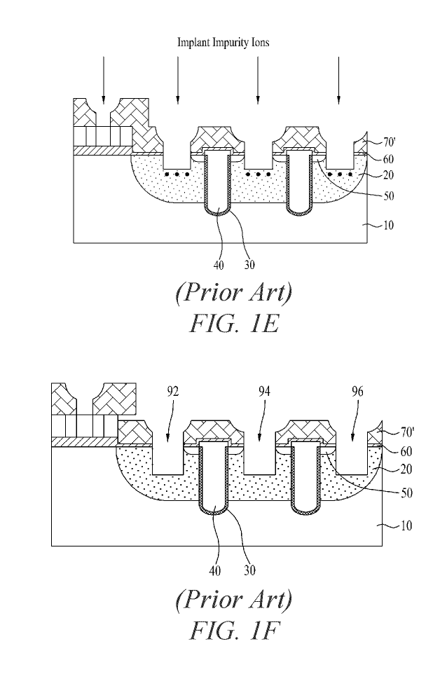

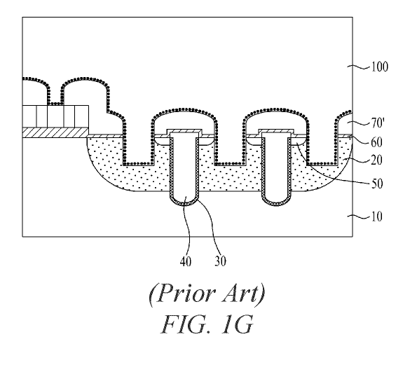

### DETAILED DESCRIPTION OF EXAMPLE EMBODIMENTS

In general, example embodiments of the present invention relate to methods for forming a metal contact in a semiconductor device. In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

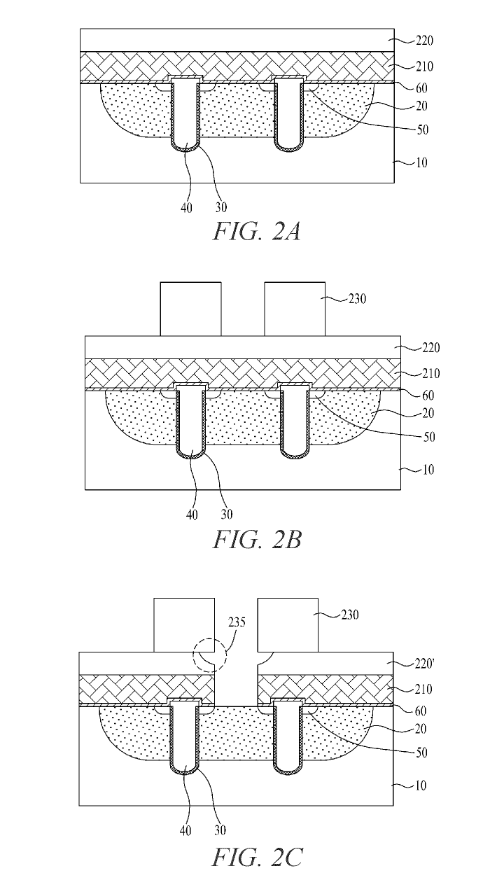

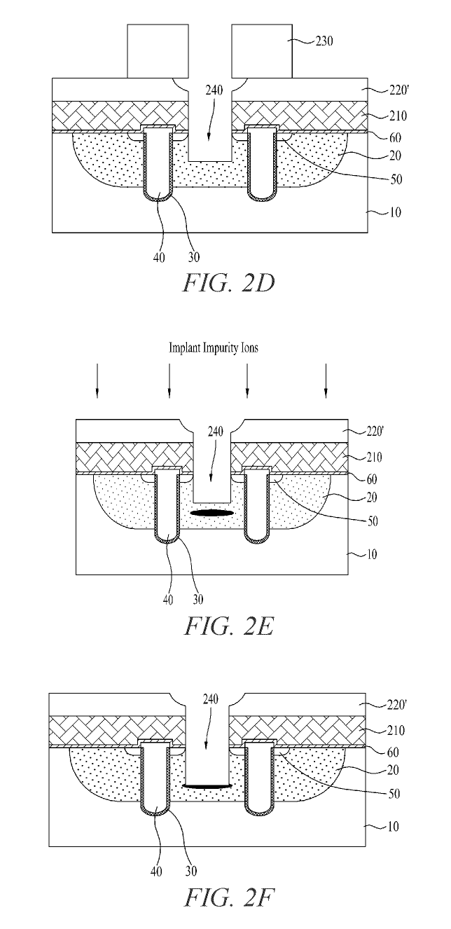

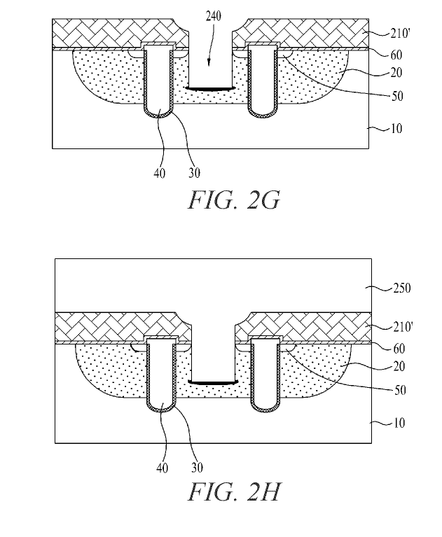

FIGS. 2A to 2H are sectional views illustrating sequential processes of an example method for forming a contact trench in a semiconductor device.

As disclosed in FIG. 2A, a lightly-doped epitaxial layer 10 is first grown over a highly-doped silicon substrate (not shown). The epitaxial layer 10 may be an N-type epitaxial layer and the silicon substrate may be an N-type silicon substrate, for example. Thereafter, impurity ions, such as boron ions, are implanted in the epitaxial layer 10, thereby forming a body 20. The impurity ions may be P-type impurity ions and the body 20 may be a P-type body, for example. At least two gate trenches are then formed in the body 20. Subsequently, a gate oxide film 30 is next formed in each of the gate trenches. Each gate trench is next filled with a polysilicon by employing a gap filling process, thereby forming at least two trench gates 40. Thereafter, N-type impurity ions are implanted into the body 20 at opposite sides of each trench gate 40, thereby forming sources 50. Thus, at least two recessed gate transistors are formed.

Next, interlayer insulating films 60 and 210 are formed over the silicon substrate that is formed with the at least two recessed gate transistors. The interlayer insulating film 60 may be formed from a tetraethoxysilane (TEOS) film and the interlayer insulating film 210 may be formed from a borophospho silicate glass (BPSG) film. Next, an insulating film 220 is deposited over the interlayer insulating film 210. The insulating film 220 may be formed from TEOS. The interlayer insulating film 60 may have a thickness between about 1,000 Å and about 2,000 Å. The interlayer insulating film 210 may have a thickness between about 4,000 Å and about 6,000 Å. The insulating film 220 may have a thickness between about 2,000 Å and about 4,000 Å.

As disclosed in FIG. 2B, a photoresist pattern 230 is next formed on the insulating film 220 using a photolithography process. As disclosed in FIG. 2C, the insulating film 220 and interlayer insulating film 210 are next sequentially etched, using the photoresist pattern 230 as an etch mask, resulting in a selectively-etched insulating film 220′ and partial exposure of the body 20 of the silicon substrate. For example, the insulating film 220 and interlayer insulating film 210 may be selectively isotropically etched using a reactive ion etch (RIE) method.

Where the insulating film 220 is a relatively hard film, the size of undercuts 235 formed in the selectively-etched insulating film 220′ beneath the photoresist pattern 230 are relatively small because the etch rate of the insulating film 220 is relatively low. However, where the insulating film 220 is a relatively soft film, the size of the undercuts 235 formed in the selectively-etched insulating film 220′ are relatively large because the etch rate of the insulating film 220 is relatively high. Although the interlayer insulating film 60 may have a relatively low etch rate corresponding to between about 1/10 and about ⅓ of the etch rate of the interlayer insulating film 210, it is possible to form a contact trench having a relatively large opening in the insulating film 220 where the insulating film 220 has an etch rate that is substantially equal to that of the interlayer insulating film 210. The relatively soft property of the interlayer insulating film 60 can be obtained when a silicon-rich process is carried out upon the deposition of the interlayer insulating film 60 such that the interlayer insulating film 60 is formed into a silicon-rich oxide film.

As disclosed in FIG. 2D, the exposed portion of the body 20 is next selectively etched, using the photoresist pattern 230 as an etch mask, to form a contact trench 240. As disclosed in FIG. 2E, the photoresist pattern 230 is next removed. Subsequently, impurity ions are implanted into the body 20 beneath the contact trench 240, using the selectively-etched insulating film 220′ as a mask. The impurity ions may be N-type impurity ions such as phosphorous (P) ions, arsenic (As) ions, or antimony (Sb) ions.

As disclosed in FIG. 2F, an isotropic etch process is next carried out for the silicon substrate. Since the isotropic etch process is carried out without using a photoresist pattern, the selectively-etched insulating film 220′ and contact trench 240 are simultaneously etched in the isotropic etch process. During the isotropic etch process, the selectively-etched insulating film 220′ functions as an etch mask. Accordingly, the selectively-etched insulating film 220′ may be formed to have a thickness capable of substantially preventing the interlayer insulating film 210 from being etched. Also, the contact trench 240 may be more deeply etched during the isotropic etch process. For example, the contact trench 240 may be more deeply etched during the isotropic etch process such that it extends further into the impurity ion implantation region arranged beneath the contact trench 240.

As disclosed in FIG. 2G, the contact trench 240 may be further etched such that contact trench 240 extends further into the body 20, the selectively-etched insulating film 220′ is completely removed, and the interlayer insulating film 210 becomes a selectively-etched interlayer insulating film 210′.

As disclosed in FIG. 2H, a metal material 250 is next deposited over the selectively-etched interlayer insulating film 210′. During this deposition, the contact trench 240 (see FIG. 2G) is also filled in by the metal material 250. The metal material 250 may be aluminum, tungsten, copper, or some combination thereof, for example.

As discussed above, the insulating film 220, which may have an etch rate similar to that of the interlayer insulating film 210, is deposited over the interlayer insulating film 210 in order to prevent the selectively-etched interlayer insulating film 210′ from being lost in the isotropic etch process carried out after the removal of the photoresist pattern 230. The insulating film 220 may exhibit a relatively easy thickness control and a relatively high productivity compared to the interlayer insulating film 210. Since the example methods disclosed herein make it possible to prevent the thickness of the interlayer insulating film 210′ from being reduced, the example methods can prevent the formation of voids during the metal material deposition process used to form metal contacts. Accordingly, the example methods disclosed herein can reduce the incidence of insulation failure and contact failure.

Although example embodiments of the present invention have been shown and described, various modifications and variations might be made to these example embodiments. The scope of the invention is therefore defined in the following claims and their equivalents.

What is claimed is:

1. A method for forming a metal contact in a semiconductor device, comprising:
forming an interlayer insulating film over a silicon substrate;
forming an insulating film over the interlayer insulating film;
forming a photoresist pattern on the insulating film;
selectively etching the insulating film, the interlayer insulating film, and the silicon substrate using the photoresist pattern as an etch mask in order to form a contact trench;
removing the photoresist pattern;
implanting impurity ions into a region beneath the contact trench using the selectively-etched insulating film as a mask;
isotropically etching the selectively-etched insulating film and the contact trench; and
filling the contact trench with a metal material.

2. The method according to claim 1, wherein:
at least two recessed transistors are formed on the silicon substrate beneath the interlayer insulating film; and
the photoresist pattern is patternized to form a contact trench between the at least two recessed transistors.

3. The method according to claim 1, wherein isotropically etching the selectively-etched insulating film and the contact trench comprises isotropically etching the selectively-etched insulating film and the contact trench using the selectively-etched insulating film as a mask such that the selectively-etched insulating film substantially blocks the interlayer insulating film from being etched.

4. The method according to claim 3, wherein isotropically etching the selectively-etched insulating film and the contact trench comprises isotropically etching the contact trench such that the contact trench extends further into the silicon substrate until the selectively-etched insulating film is removed.

5. The method according to claim 4, wherein isotropically etching the selectively-etched insulating film and the contact trench comprises isotropically etching the contact trench such that the contact trench extends to the impurity ion implantation region arranged beneath the contact trench.

6. The method according to claim 2, wherein the insulating film has an etch rate that is substantially equal to an etch rate of the interlayer insulating film.

7. The method according to claim 2, wherein the insulating film has an etch rate that is lower than an etch rate of the interlayer insulating film.

8. The method according to claim 2, wherein the interlayer insulating film is formed from a tetraethoxysilane (TEOS) film and a borophospho silicate glass (BPSG) film.

9. The method according to claim 8, wherein the insulating film is formed from TEOS.

10. The method according to claim 9, wherein the TEOS film of the interlayer insulating film has a thickness between about 1,000 Å and about 2,000 Å.

11. The method according to claim 10, wherein the BPSG film of the interlayer insulating film has a thickness between about 4,000 Å and about 6,000 Å.

12. The method according to claim 11, wherein the TEOS insulating film has a thickness between about 2,000 Å and about 4,000 Å.
